(19) United States
(12) Patent Application Publication
(10) Pub. No.: US 2025/0204176 A1
(43) Pub. Date: Jun. 19, 2025

(54) DISPLAY DEVICE

(71) Applicant: Samsung Display Co., Ltd., Yongin-Si (KR)

(72) Inventors: Beom Yeol PARK, Yongin-si (KR); Kang San KIM, Yongin-si (KR); Yun Ji LEE, Yongin-si (KR); Kyung Soo JANG, Yongin-si (KR); Nak Cho CHOI, Yongin-si (KR)

(21) Appl. No.: 18/760,036

(22) Filed: Jul. 1, 2024

(30) Foreign Application Priority Data
Dec. 15, 2023 (KR) 10-2023-0183449

(51) Int. Cl. H10K 59/126

(52) U.S. Cl. CPC H10K 59/126

(57) ABSTRACT

A display device includes a substrate, a light emitting element layer on the substrate and including a plurality of light emitting elements, and a light control layer on the light emitting element layer. The light control layer includes a light transmitting film including regions spaced apart from each other, a first stopper layer disposed on the light transmitting film, and a light blocking film including regions on the first stopper layer and disposed between the regions of the light transmitting film. The first stopper layer covers upper surfaces and side surfaces of the regions of the light transmitting film.

### CROSS-REFERENCE TO RELATED APPLICATION

This application claims priority from Korean Patent Application No. 10-2023-0183449 filed on Dec. 15, 2023, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### Description of the Related Art

The demand for devices capable of displaying images has increased and diversified as our information society has advanced. Some common display devices currently include liquid crystal displays (LCDs), field emission displays (FEDs), and light emitting displays (LEDs). A light emitting display may, for example, be an organic light emitting display including organic light emitting diode elements as light emitting elements or an inorganic light emitting display including inorganic light emitting diode elements as light emitting elements.

A display device may need a controlled or limited viewing angle for some applications. For example, the viewing angle for an image displayed on a display device in front of a driver or a passenger in a vehicle may need to be restricted to prevent the image from reflecting from a windshield and hindering driving of the vehicle. The viewing angle of the image displayed on the display device for a vehicle may also need to be controlled to protect privacy, for example, so that the image displayed on the display device in front of the driver is not visible to the passenger.

### SUMMARY

Aspects of the present disclosure may provide a display device in which reliability of a light control layer is improved.

Aspects of the present disclosure may also improve a process of forming a light control layer in a display device.

Aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device may include a substrate, a light emitting element layer disposed on the substrate and including a plurality of light emitting elements, and a light control layer disposed on the light emitting element layer. The light control layer may include a light transmitting film including a plurality of regions spaced apart from each other, a first stopper layer disposed on the light transmitting film, and a light blocking film including a plurality of regions disposed on the first stopper layer and disposed between the regions of the light transmitting film. The first stopper layer covers upper surfaces and side surfaces of the regions of the light transmitting film.

In an embodiment, the first stopper layer is conformally disposed on the regions of light transmitting film.

In an embodiment, each of the regions of the light blocking film includes a protrusion portion protruding from an upper surface of the first stopper layer or the upper surfaces of the light transmitting film.

In an embodiment, the display device may further comprise an overcoat layer disposed on the first stopper layer and the regions of the light blocking film and covering an upper surface and side surfaces of the protrusion portion.

In an embodiment, the display device may further comprise a second stopper layer disposed on the regions of the light blocking film, wherein the second stopper layer includes a plurality of regions respectively disposed on the regions of the light blocking film.

In an embodiment, the second stopper layer includes an inorganic material, and the light transmitting film includes an organic material.

In an embodiment, the light control layer further includes a plurality of regions of a light transmitting lower film respectively disposed below the regions of light transmitting film.

In an embodiment, the light transmitting lower film includes an inorganic material, and the light transmitting film includes an organic material.

In an embodiment, the display device may further comprise a dam disposed on one side of the plurality of light emitting elements on the substrate and including the same material as the light transmitting lower film.

In an embodiment, the regions of light transmitting film are disposed closer to the plurality of light emitting elements than is the dam.

According to an aspect of the present disclosure, there is provided a display device including, a substrate, a light emitting element layer disposed on the substrate and including a plurality of light emitting elements, and a light control layer disposed on the light emitting element layer, wherein the light control layer includes, a light transmitting film including a plurality of first openings, a first stopper layer disposed on the light transmitting film, and a light blocking film including a plurality of regions disposed on the first stopper layer and disposed in the plurality of first openings, respectively, and the first stopper layer covers an upper surface of the light transmitting film and inner surfaces of the plurality of first openings.

In an embodiment, the first stopper layer is conformally disposed on the light transmitting film.

In an embodiment, each of the regions of the light blocking film includes a protrusion portion protruding from an upper surface of the first stopper layer or the upper surface of the light transmitting film.

In an embodiment, the display device may further comprise an overcoat layer disposed on the first stopper layer and the regions of light blocking film and covering an upper surface and side surfaces of the protrusion portion.

In an embodiment, the display device may further comprise a second stopper layer disposed on the regions of the light blocking film, wherein the second stopper layer includes a plurality of regions respectively disposed on the regions of the light blocking film.

In an embodiment, the second stopper layer includes an inorganic material, and the light transmitting film includes an organic material.

In an embodiment, the light control layer further includes a light transmitting lower film disposed below the light transmitting film and including a plurality of second openings, and the plurality of second openings are formed integrally with the plurality of first openings, respectively.

In an embodiment, the light transmitting lower film includes an inorganic material, and the light transmitting film includes an organic material.

In an embodiment, the display device may further comprise a dam disposed on one side of the plurality of light emitting elements on the substrate and including the same material as the light transmitting lower film.

In an embodiment, the light transmitting film is disposed closer to the plurality of light emitting elements than the dam is.

According to a display device according to an embodiment of the present disclosure, visibility of a light control layer may be improved.

According to the display device according to an embodiment of the present disclosure, efficiency of a process of forming a light control layer may be improved.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings.

FIG. 1 is an exploded perspective view illustrating a display device according to an embodiment.

FIG. 2 is a plan view illustrating the display device according to the embodiment of FIG. 1.

FIG. 3 is a schematic cross-sectional view of the display device taken along line X1-X1′ of FIG. 2.

FIG. 4 is a schematic diagram illustrating use of the display device according to an embodiment in a vehicle.

FIG. 5 is a cross-sectional view illustrating an example of a display panel according to an embodiment.

FIG. 6 is a plan view illustrating a portion of a display area according to an embodiment.

FIG. 7 is a cross-sectional view of an embodiment of the display area taken along line X2-X2′ of FIG. 6.

FIG. 8 is also a cross-sectional view of an embodiment of the display area taken along the line X2-X2′ of FIG. 6.

FIG. 9A is a cross-sectional view illustrating portions of a display area and a non-display area of a display panel according to an embodiment.

FIG. 9B is also a cross-sectional view illustrating portions of a display area and a non-display area of a display panel according to an embodiment.

FIG. 10 is a flowchart illustrating a method of manufacturing a display device according to an embodiment.

FIGS. 11, 12, and 13 are cross-sectional views illustrating formation of light transmitting film during an embodiment of the method of FIG. 10.

FIG. 14 is a cross-sectional view illustrating formation of a first stopper layer during an embodiment of the method of FIG. 10.

FIG. 15 is a cross-sectional view illustrating formation of a light blocking material layer during an embodiment of the method of FIG. 10;

FIGS. 16 and 17 are cross-sectional views illustrating formation of a second stropper layer during an embodiment of the method of FIG. 10.

FIG. 18 is a cross-sectional view illustrating patterning of the light blocking material layer during an embodiment of the method of FIG. 10.

FIG. 19 is a cross-sectional view illustrating formation of an overcoat layer during an embodiment of the method of FIG. 10.

### DETAILED DESCRIPTION OF THE EMBODIMENTS

Example embodiments will now be described more fully hereinafter with reference to the accompanying drawings. Other embodiments in accordance with this disclosure may take different forms, and embodiments in accordance with this disclosure should not be construed as limited to the example embodiments. Rather, the example embodiments are provided so that this disclosure will be thorough and complete, and will fully convey an understanding of this disclosure to those skilled in the art.

A layer referred to herein as being “on” another layer or substrate may be directly on the other layer or substrate or one or more intervening layers may also be present. The same reference numbers used in the various drawings and throughout this specification indicate the same components.

Hereinafter, embodiments of the present disclosure are described in detail with reference to the accompanying drawings.

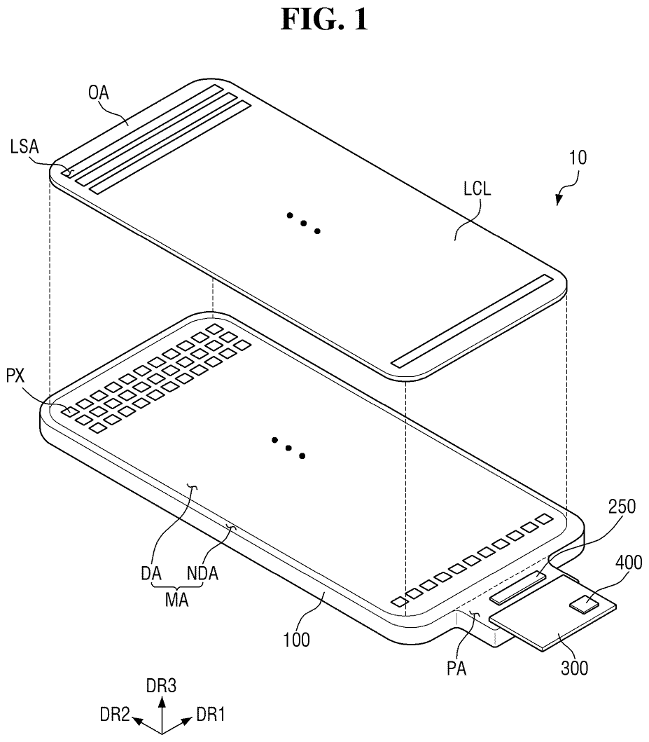

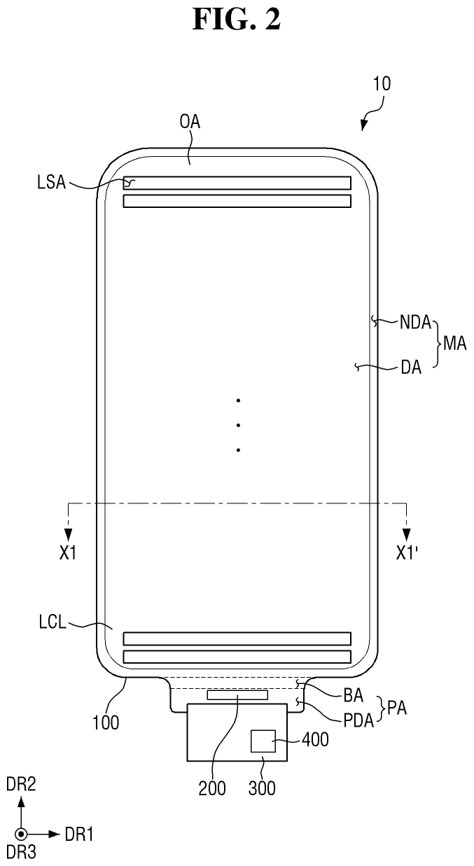

FIG. 1 is an exploded perspective view illustrating a display device according to an embodiment. FIG. 2 is a plan view of the display device according to an embodiment of FIG. 1.

Referring to FIGS. 1 and 2, a display device 10 may be a device capable of displaying a moving image or a still image and may be used in various applications or products such as vehicles, televisions, laptop computers, monitors, billboards, and the Internet of Things (IoT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

In some embodiments, the display device 10 is used as a display screen in a vehicle, and the display device 10 may be referred to as a display for a vehicle. The display for a vehicle may provide to a user various service information such as a convenience function and media information, driving information, and status information of the vehicle. When the display device 10 includes an input device such as a touch panel, the user may operate a driving mode of the vehicle and various functions such as a convenience function through the display device 10.

The display device 10 may, for example, be an organic light emitting display, a liquid crystal display, a plasma display panel, a field emission display, an electrophoretic display, an electro-wetting display, a quantum dot light emitting display, or a micro light emitting diode (LED) display. The following mainly describes examples in which the display device 10 is an organic light emitting display, but the present disclosure is not limited thereto.

The display device 10 according to an embodiment may include a display panel 100, a display driving circuit 250, a circuit board 300, and a touch driving circuit 400.

The display panel 100 may include a plurality of pixels PX arranged in a first direction DR1 and a second direction DR2. Each of the pixels PX may have a rectangular, square, or rhombic shape in plan view. For example, as illustrated in FIG. 1, each of the pixels PX may have a square shape in plan view. However, each of the pixels PX is not limited thereto and may have various shapes such as a polygonal shape, a circular shape, and an elliptical shape in plan view.

In the drawings, the first direction DR1 and the second direction DR2 are horizontal directions and at a non-zero angle to each other. For example, the first direction DR1 and the second direction DR2 may be orthogonal to each other. In addition, a third direction DR3 may be a direction, for example, orthogonal to, a plane defined by the first direction DR1 and the second direction DR2. In the present specification, directions of arrows associated with the first to third directions DR1, DR2, and DR3 in the drawings may be referred to as positive directions and directions opposite to the arrows may be referred to as negative directions, and unless otherwise specified, each of the first to third directions DR1, DR2, and DR3 may include both the corresponding positive and negative directions. The phrase “in plan view” as used herein refers to a view along the third direction DR3.

The display panel 100 may include a main area MA and a protrusion area PA protruding from one side of the main area MA.

The main area MA may have a substantially rectangular shape, in plan view, with short sides extending in the first direction DR1 and long sides extending in the second direction DR2. A corner where the short side in the first direction DR1 and the long side in the second direction DR2 meet may be a right angle or may be rounded with a predetermined curvature. The shape of the display device 10 in plan view is not limited to the rectangular shape and may, for example, be other polygonal shapes, a circular shape, or an elliptical shape. The main area MA may be flat but is not limited thereto, and the main area MA may include curved surface portions formed at left and right ends thereof. In this case, the curved surface portions may have a constant curvature or a variable curvature.

The main area MA may include a display area DA where the pixels PX display an image, and a non-display area NDA, which is a peripheral area of the display area DA.

The pixels PX and scan lines, data lines, and power lines connected to the pixels PX may be disposed in the display area DA. When the main area MA includes the curved surface portions, the display area DA may extend onto the curved surface portions. In this case, the image may be visible even on the curved surface portions of the display panel 100.

The non-display area NDA may be defined as an area from an outer edge of the display area DA to an edge of the display panel 100. The non-display area NDA may contain a scan driver for applying scan signals to the scan lines and link lines connecting the data lines and the display driving circuit 250 to each other.

The protrusion area PA may protrude from one side of the main area MA. For example, the protrusion area PA may protrude from a lower side of the main area MA, as illustrated in FIG. 2. A length of the protrusion area PA in the first direction DR1 may be smaller than a length of the main area MA in the first direction DR1.

The protrusion area PA may include a bending area BA and a pad area PDA. In this case, the pad area PDA may be disposed on one side of the bending area BA, and the main area MA may be disposed on the other side of the bending area BA. For example, the pad area PDA may be disposed on a lower side of the bending area BA, and the main area MA may be disposed on an upper side of the bending area BA.

The display panel 100 may be flexible to allow curving, bending, folding, or rolling of the display panel 100. The display panel 100 may be bent in a thickness direction, that is, the third direction DR3, in the bending area BA. In this case, one surface of the pad area PDA of the display panel 100 may face upward as shown in FIG. 1 before the display panel 100 is bent, but the pad area PDA may face downward after the bending area BA of the display panel 100 is bent. For this reason, the pad area PDA may be disposed below the main area MA and may thus overlap the main area MA.

Pads electrically connected to the display driving circuit 250 and the circuit board 300 may be disposed in the pad area PDA of the display panel 100.

The display driving circuit 250 outputs signals and voltages for driving the display panel 100. For example, the display driving circuit 250 may supply data voltages to the data lines. In addition, the display driving circuit 250 may supply source voltages to the power lines and may supply scan control signals to the scan driver. The display driving circuit 250 may be formed as an integrated circuit (IC) and mounted on the display panel 100 in the pad area PDA in a chip on glass (COG) manner, a chip on plastic (COP) manner, or an ultrasonic bonding manner, but the display driving circuit 250 is not limited thereto. For example, the display driving circuit 250 may be mounted on the circuit board 300.

The pads may include display pads electrically connected to the display driving circuit 250 and touch pads electrically connected to touch lines.

The circuit board 300 may be attached onto the pads using an anisotropic conductive film. In particular, lead lines of the circuit board 300 may be electrically connected to the pads. The circuit board 300 may be a flexible printed circuit board, a printed circuit board, or a flexible film such as a chip on film.

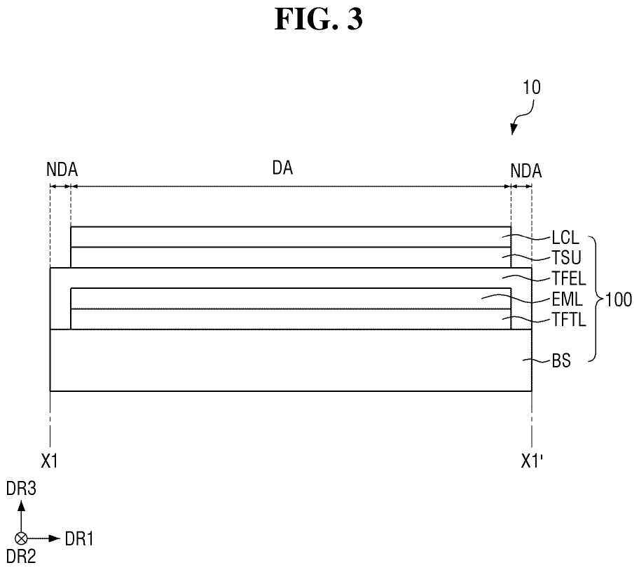

The touch driving circuit 400 may be connected to touch electrodes of a touch sensor layer TSU (see FIG. 3) of the display panel 100. The touch driving circuit 400 may apply driving signals to the touch electrodes of the touch sensor layer TSU (see FIG. 3) and may measure capacitance values of the touch electrodes. The driving signal may be a signal having a plurality of driving pulses. The touch driving circuit 400 may not only decide whether or not a touch has been input according to the capacitance values but may also calculate touch coordinates where the touch has been input.

The touch driving circuit 400 may be disposed on the circuit board 300. The touch driving circuit 400 may be formed as an integrated circuit (IC) and mounted on the circuit board 300.

In the display device 10 according to the present embodiment, the display panel 100 may further include a light control layer LCL.

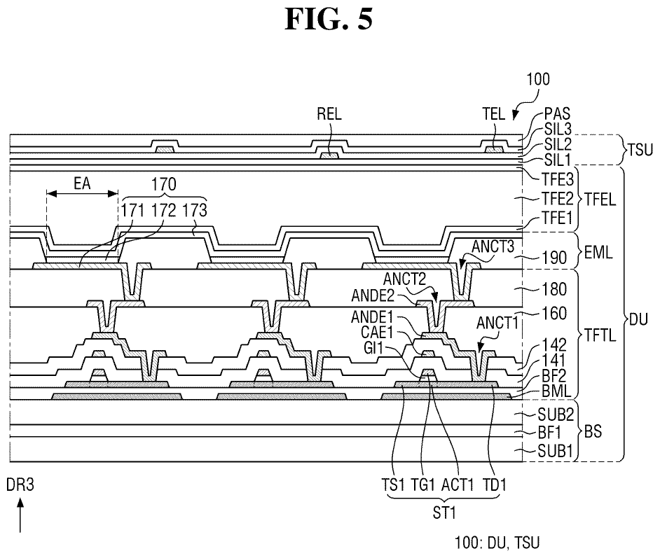

The light control layer LCL may be disposed directly on the main area MA of the display panel 100. For example, the light control layer LCL may be embedded in the display panel 100 and directly on the main area MA of the display panel 100. The light control layer LCL may be embedded in the display panel 100 to reduce a thickness and a manufacturing cost of the display device 10 compared to an embodiment where a separate light control film is attached to the display panel 100. The light control layer LCL may adjust a viewing angle of light emitted from a light emitting layer 172 (see FIG. 5) of the display panel 100. In some embodiments, the light control layer LCL may be disposed on the display area DA of the main area MA. However, the present disclosure is not limited thereto, and a size of the light control layer LCL may also be greater than a size of the display area DA in plan view. In this case, the light control layer LCL may overlap both the display area DA and the non-display area NDA.

In some embodiments, the light control layer LCL may include a transmissive area OA and non-transmissive areas LSA.

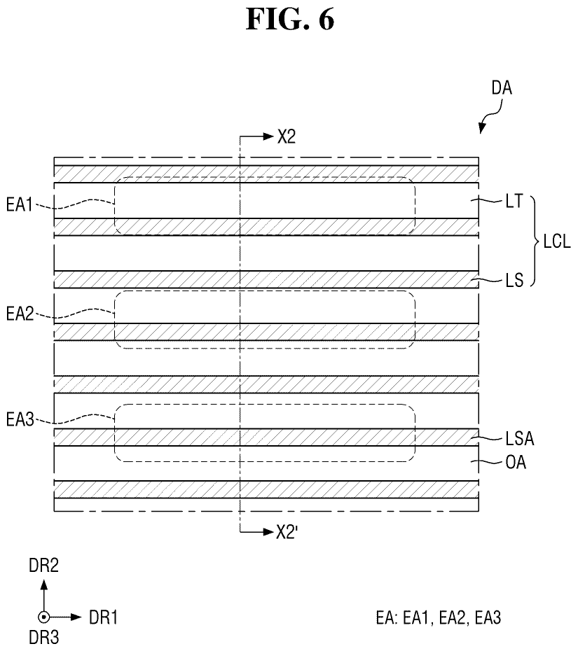

The transmissive area OA may be an area where a light blocking film LS (see FIG. 6) is not present. The transmissive area OA may be an area transmitting light therethrough.

A perimeter of the transmissive area OA may have a substantially rectangular shape in plan view as illustrated in FIGS. 1 and 2 but is not limited thereto. The transmissive area OA may have a circular shape, an elliptical shape, or a polygonal shape in plan view. In some embodiments, a shape of the perimeter of the transmissive area OA may substantially correspond to the shape of perimeter of the display panel 100.

The non-transmissive areas LSA may be areas containing the light control layer LCL. The non-transmissive areas LSA may be areas where regions of the light blocking film LS (see FIG. 6) are disposed.

In some embodiments, the non-transmissive areas LSA may include stripes extending in the first direction DR1 or the second direction DR2. As an example, as illustrated in FIG. 1, the stripes forming the non-transmissive areas LSA may extend in the first direction DR1 and may be arranged along the second direction DR2. As another example, stripes forming the non-transmissive area LSA may extend in the second direction DR2 and may be arranged along the first direction DR1. As still another example, some of the non-transmissive areas LSA may be stripes extending in the first direction DR1 and may be arranged along the second direction DR2, while the others of the non-transmissive areas LSA may be stripes extending in the second direction DR2 and may be arranged along the first direction DR1.

In an embodiment, as illustrated in FIG. 1, when the non-transmissive areas LSA are arranged along the second direction DR2, the viewing angle may be controlled in the second direction DR2. In another embodiment, when the non-transmissive areas LSA are arranged along the first direction DR1, the viewing angle may be controlled in the first direction DR1. In the display device 10 according to the present disclosure, arrangements and shapes of the transmissive area OA and the non-transmissive areas LSA may be variously modified depending on a required viewing angle control direction.

FIGS. 1 and 2 illustrate an example in which the transmissive area OA surrounds the non-transmissive areas LSA, but the present disclosure is not limited thereto. In some embodiments, the transmissive area OA may include a plurality of separated transmissive areas OA, the separated transmissive areas OA may extend between adjacent non-transmissive areas LSA in the same direction as the non-transmissive areas LSA, and the plurality of transmissive areas OA and the non-transmissive areas LSA may be alternately disposed. For example, as illustrated in FIG. 1, when the non-transmissive areas LSA extend in the first direction DR1, the plurality of transmissive areas OA may extend in the first direction DR1 and may be disposed alternately with the non-transmissive areas LSA in the second direction DR2.

The light control layer LCL may include a light blocking film LS (see FIG. 6) blocking light emitted from a light emitting layer 172 (see FIG. 5) of the display panel 100 and include a light transmitting film LT (see FIG. 6) transmitting the light therethrough. A detailed structure of the light control layer LCL is described further below.

FIG. 3 is a schematic cross-sectional view of the display device 10 taken along line X1-X1′ of FIG. 2.

Referring to FIG. 3, the display device 10 may include the display panel 100 in which the light control layer LCL is embedded. The display panel 100 may include a base member BS, a thin film transistor layer TFTL, a light emitting element layer EML, a thin film encapsulation layer TFEL, the touch sensor layer TSU, and the light control layer LCL.

The base member BS may include a substrate. The substrate may be made of an insulating material such as glass, quartz, or a polymer resin. Examples of the polymer resin may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or combinations thereof. Alternatively, the substrate may include a metal material.

The substrate in the base member BS may be a rigid substrate or be a flexible substrate that may be bent, folded, or rolled. When the substrate is the flexible substrate, the substrate may be made of polyimide (PI), but the disclosure is not limited thereto.

The thin film transistor layer TFTL may be disposed on the base member BS. The scan lines, the data lines, the power lines, scan control lines, routing lines connecting the pads and the data lines to each other, and the like, as well as thin film transistors of each of the pixels may be formed in the thin film transistor layer TFTL. Each of the thin film transistors may include a gate electrode, a semiconductor layer, a source electrode, and a drain electrode.

The thin film transistor layer TFTL may be disposed in the display area DA and the non-display area NDA. Specifically, the thin film transistors of each of the pixels, the scan lines, the data lines, and the power lines of the thin film transistor layer TFTL may be disposed in or extend into the display area DA. The scan control lines and the link lines of the thin film transistor layer TFTL may be disposed in the non-display area NDA.

The light emitting element layer EML may be disposed on the thin film transistor layer TFTL. The light emitting element layer EML may include light emitting elements of the pixels. Each light emitting element may include a first electrode, a light emitting layer, and a second electrode in the light emitting element layer EML, and the light emitting element layer EML may further include a pixel defining film defining the areas of the light emitting elements. The light emitting layer in each light emitting element may be an organic light emitting layer including an organic material. In this case, the light emitting layer may include a hole transporting layer, an organic light emitting layer, and an electron transporting layer. When a predetermined voltage is applied through the thin film transistor of the thin film transistor layer TFTL to the first electrode of a light emitting element and a cathode voltage is applied to the second electrode of the light emitting element, holes and electrons may move to the organic light emitting layer through the hole transporting layer and the electron transporting layer, respectively, and are combined with each other in the organic light emitting layer to emit light. The light emitting areas of the pixels defined in the light emitting element layer EML may be disposed in the display area DA.

The thin film encapsulation layer TFEL may be disposed on the light emitting element layer EML. The thin film encapsulation layer TFEL may serve to prevent oxygen or moisture from permeating into the light emitting element layer EML. To this end, the thin film encapsulation layer TFEL may include at least one inorganic film. The inorganic film may be a silicon nitride layer, a silicon oxynitride layer, a silicon oxide layer, a titanium oxide layer, or an aluminum oxide layer but is not limited thereto. In addition, the thin film encapsulation layer TFEL may serve to protect the light emitting element layer EML from foreign substances such as dust. To this end, the thin film encapsulation layer TFEL may include at least one organic film. The organic film may be made of an acrylic resin, an epoxy resin, a phenolic resin, a polyamide resin, or a polyimide resin, but is not limited thereto.

The thin film encapsulation layer TFEL may be disposed in both the display area DA and the non-display area NDA. Specifically, the thin film encapsulation layer TFEL may cover the light emitting element layer EML of the display area DA and the non-display area NDA and cover edges of the thin film transistor layer TFTL in the non-display area NDA.

The touch sensor layer TSU may be disposed on the thin film encapsulation layer TFEL. Since the touch sensor layer TSU may be directly on the thin film encapsulation layer TFEL, a thickness of the display device 10 may be reduced compared to a case where a separate touch panel including the touch sensor layer TSU is attached, e.g., using an adhesive layer, on the thin film encapsulation layer TFEL.

The touch sensor layer TSU may include touch electrodes for sensing a user's touch in a capacitance manner and touch lines connecting the touch electrodes to the pads. For example, the touch sensor layer TSU may be used to sense the user's touch in a self-capacitance manner or a mutual capacitance manner.

The touch electrodes of the touch sensor layer TSU may be disposed in a touch sensor area overlapping the display area DA. The touch lines of the touch sensor layer TSU may be disposed in a touch peripheral area overlapping the non-display area NDA.

The light control layer LCL may be disposed on the touch sensor layer TSU. The light control layer LCL may be disposed to overlap the display area DA. The light control layer LCL may serve to absorb or block light traveling at angles greater than a predetermined angle with respect to the third direction DR3 among light emitted from the light emitting element layer EML. That is, the light control layer LCL may control or limit the directions at which light may propagate from the display device 10 and thereby control a viewing angle for images that the display device 10 displays.

Although not illustrated in FIG. 3, the display device 10 may further include a cover window. The cover window may be additionally disposed on the light control layer LCL, and in this case, the light control layer LCL and the cover window may be attached to each other by a transparent adhesive member such as an optically clear adhesive (OCA) film.

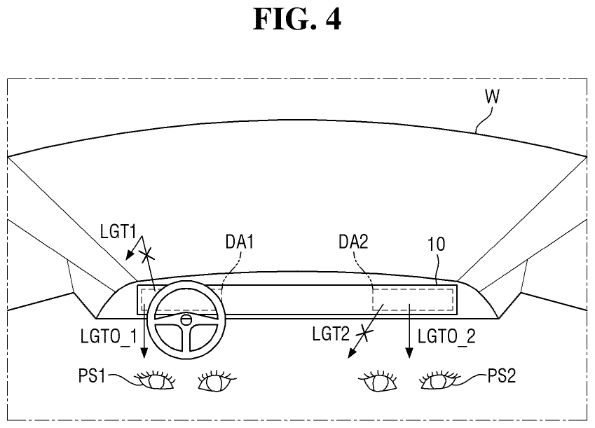

FIG. 4 is a schematic diagram illustrating an embodiment in which the display device 10 is used in a vehicle.

Referring to FIG. 4, the display device 10 according to an embodiment may be, for example, a display device in a vehicle. The vehicle may include a vehicle body that defines an indoor space of the vehicle. The vehicle body may include a windshield W protecting a driver PS1 and a passenger PS2 from the outside while providing a field of view to the driver PS1.

The display device 10 may be provided in the indoor space, as illustrated in FIG. 4. In some embodiments, the display device 10 may be disposed on a dashboard provided in the indoor space. FIG. 4 illustrates an example in which the display device 10 may extend from an area of the dashboard positioned in front of a driver's seat to an area of the dashboard positioned in front of a passenger seat. For example, the display device 10 may be an integrated display covering an area of the dashboard from in front of the driver's seat to in front of the passenger seat.

In the example shown in FIG. 4, the display device 10 may include a first display area DA1 positioned in front of the driver's seat and a second display area DA2 positioned in front of the passenger seat. The first display area DA1, which may be disposed on the dashboard in front of a driver's seat, may provide speed information and the like to the driver PS1, and the second display area DA2, which may be disposed on the dashboard in front of the passenger seat, may provide entertainment information and the like to the passenger PS2. Although not illustrated in FIG. 4, the display device 10 may further include a third display area between the first display area DA1 and the second display area DA2. As another example, separate display devices 10 may be disposed on the dashboard, one positioned in front of the driver's seat and one positioned in front of the passenger seat. For example, a first display device may be disposed on the dashboard positioned in front of the driver's seat, and a second display device may be disposed on the dashboard positioned in front of the passenger seat.

The driver PS1 may recognize (see or view) a display screen of the display device 10 through light LGT0_1 emitted from a portion of the display device 10 positioned in front of the driver's seat toward the driver PS1. However, some light LGT1 of the light emitted from the portion of the display device 10 positioned in front of the driver's seat may be reflected from the surrounding windshield W and directed toward the driver PS1. In this case, the driver PS1 may see the image reflected in the windshield W, and the image reflected from the windshield W may hinder the driving of the driver PS1. On the other hand, in the case of the display device 10 according to an embodiment, the display device 10 may have a viewing angle, particularly, a vertical viewing angle, that is controlled or limited to prevent at least some light LGT1 from being emitted in a direction that would be reflected from the windshield W and directed toward the driver PS1.

The passenger PS2 may recognize (see or view) a display screen of the display device 10 through light LGT0_2 emitted toward the passenger PS2 from a portion of the display device 10 positioned in front of the passenger seat. However, some light LGT2 of the light emitted from the portion of the display device 10 positioned in front of the passenger seat may be directed toward the driver PS1. In accordance with an embodiment, when the vehicle is driving, the display device 10 may, for safety reasons, prevent the driver PS1 from seeing the image displayed in the display area DA2. In accordance with an aspect of the present disclosure, the display device 10 may have a viewing angle, particularly a horizontal viewing angle, for the light emitted from the display area DA2 of the display device 10 that prevents at least some light LGT2 emitted from the display area DA2 from being directed to the driver PS1.

FIG. 4 shows an example in which the portion of the display device 10 positioned in front of the driver's seat controls or limits the vertical viewing angle and the portion of the display device 10 positioned in front of the passenger seat controls or limits the horizontal viewing angle, but the present disclosure is not limited thereto. As an example, the portion of the display device 10 positioned in front of the driver's seat may adjust the horizontal viewing angle, and the portion of the display device 10 positioned in front of the passenger seat may adjust the vertical viewing angle. As another example, portions of the display device 10 positioned in front of the driver's seat and positioned in front of the passenger seat may control or limit both the vertical viewing angle and the horizontal viewing angle.

The light control layer LCL may be configured to provide the desired control or limitation of the viewing angle. The light control layer LCL may, for example, limit viewing angle may to be in a predetermined angle range. As a more specific example, the viewing angle may be an angle within 35° from a normal extending in a direction perpendicular to a display surface of the display device 10 facing the driver PS1 or the passenger PS2. In some embodiments, the angle within 35° from the normal may be defined as an effective viewing angle, but the present disclosure is not limited thereto.

FIG. 5 is a cross-sectional view illustrating an example of a display panel according to an embodiment.

Referring to FIG. 5, the display panel 100 may include a display layer DU and a touch sensor layer TSU. The display layer DU may include a base member BS, a thin film transistor layer TFTL, a light emitting element layer EML, and a thin film encapsulation layer TFEL.

The base member BS may include a first substrate SUB1, a first buffer film BF1 disposed on the first substrate SUB1, and a second substrate SUB2 disposed on the first buffer film BF1.

Each of the first substrate SUB1 and the second substrate SUB2 may be made of an insulating material such as glass, quartz, or a polymer resin. Examples of the polymer resin may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or combinations thereof. Alternatively, each of the first substrate SUB1 and the second substrate SUB2 may include a metal material.

Each of the first substrate SUB1 and the second substrate SUB2 may be a rigid substrate or be a flexible substrate that may be bent, folded, or rolled. When each of the first substrate SUB1 and the second substrate SUB2 is the flexible substrate, each of the first substrate SUB1 and the second substrate SUB2 may be made of polyimide (PI), but the disclosure is not limited thereto.

The first buffer film BF1 may be a film that protects a first thin film transistor ST1 and a light emitting layer 172 from moisture that might otherwise permeate through the first substrate SUB1 and the second substrate SUB2, which may be vulnerable to moisture permeation. The first buffer film BF1 may include a plurality of inorganic films that are stacked. For example, the first buffer film BF1 may be formed as multiple films in which one or more inorganic films of a silicon nitride layer, a silicon oxynitride layer, a silicon oxide layer, a titanium oxide layer, and an aluminum oxide layer are alternately stacked.

The thin film transistor layer TFTL may include bottom metal layers BML, a second buffer film BF2, first thin film transistors ST1, a first gate insulating film GI1, gate electrodes TG1, a first interlayer insulating film 141, first capacitor electrodes CAE1, a second interlayer insulating film 142, first anode connection electrodes ANDE1, a first organic film 160, second anode connection electrodes ANDE2, and a second organic film 180.

The bottom metal layer BML may be disposed on the second substrate SUB2. The bottom metal layer BML may overlap a first active layer ACT1 of the first thin film transistor ST1 in the third direction DR3 and may prevent generation leakage current when light is incident on the first active layer ACT1 of the first thin film transistor ST1. The bottom metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof, and the bottom metal layer BML may be patterned to form a plurality of separated regions underlying corresponding thin film transistors such as the first thin film transistor ST1. The bottom metal layer BML may be omitted.

The second buffer film BF2 may be disposed on the bottom metal layer BML. The second buffer film BF2 may protect the first thin film transistor ST1 and the light emitting layer 172 from moisture permeating through the first substrate SUB1 and the second substrate SUB2, which may be vulnerable to moisture permeation. The second buffer film BF2 may include a plurality of inorganic films that are stacked. For example, the second buffer film BF2 may be formed as multiple films in which one or more inorganic films of a silicon nitride layer, a silicon oxynitride layer, a silicon oxide layer, a titanium oxide layer, and an aluminum oxide layer are alternately stacked.

The first active layer ACT1 of the first thin film transistor ST1 may be disposed on the second buffer film BF2. The first active layer ACT1 of the first thin film transistor ST1 may include polycrystalline silicon, single crystal silicon, low-temperature polycrystalline silicon, amorphous silicon, or an oxide semiconductor. The first active layer ACT1 of the first thin film transistor ST1 not overlapping the first gate insulating film GI1 may be doped with impurities or ions and may thus be conductive. Therefore, a first source electrode TS1 and a first drain electrode TD1 of the first active layer ACT1 of the first thin film transistor ST1 may be formed.

The first gate insulating film GI1 may be disposed on the first active layer ACT1 of the first thin film transistor TFT1. FIG. 5 illustrates an example in which the first gate insulating film GI1 between a first gate electrode TG1 and the first active layer ACT1 of the first thin film transistor ST1, but the present disclosure is not limited thereto. The first gate insulating film GI1 may also be between the first interlayer insulating film 141 and the first active layer ACT1 and between the first interlayer insulating film 141 and the second buffer film BF2. The first gate insulating film GI1 may be formed as an inorganic film such as a silicon nitride layer, a silicon oxynitride layer, a silicon oxide layer, a titanium oxide layer, or an aluminum oxide layer.

The first gate electrode TG1 of the first thin film transistor ST1 may be disposed on the first gate insulating film GI1. The first gate electrode TG1 of the first thin film transistor ST1 may overlap the first active layer ACT1 in the third direction DR3. The first gate electrode TG1 of the first thin film transistor ST1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating film 141 may be disposed on the first gate electrode TG1 of the first thin film transistor ST1. The first interlayer insulating film 141 may be formed as an inorganic film such as a silicon nitride layer, a silicon oxynitride layer, a silicon oxide layer, a titanium oxide layer, or an aluminum oxide layer. The first interlayer insulating film 141 may include a plurality of inorganic films.

The first capacitor electrodes CAE1 may be disposed on the first interlayer insulating film 141. An associated one of the first capacitor electrodes CAE1 may overlap the first gate electrode TG1 of the first thin film transistor ST1 in the third direction DR3. The first interlayer insulating film 141 may have a predetermined dielectric constant, and a capacitor may be formed by the first capacitor electrode CAE1, the first gate electrode TG1, and the first interlayer insulating film 141 disposed between the first capacitor electrode CAE1 and the first gate electrode TG1. The first capacitor electrodes CAE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second interlayer insulating film 142 may be disposed on the first capacitor electrodes CAE1. The second interlayer insulating film 142 may be formed as an inorganic film such as a silicon nitride layer, a silicon oxynitride layer, a silicon oxide layer, a titanium oxide layer, or an aluminum oxide layer. The second interlayer insulating film 142 may include a plurality of inorganic films.

The first anode connection electrodes ANDE1 may be disposed on the second interlayer insulating film 142. An associated one of the first anode connection electrodes ANDE1 may be connected to the first drain electrode TD1 of the first thin film transistor ST1 through a first anode contact hole ANCT1 penetrating through the first interlayer insulating film 141 and the second interlayer insulating film 142 to the first drain electrode TD1 of the first thin film transistor ST1. The first anode connection electrodes ANDE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first organic film 160 for planarization may be disposed on the first anode connection electrodes ANDE1. The first organic film 160 may be formed as an organic film made of an acrylic resin, an epoxy resin, a phenolic resin, a polyamide resin, a polyimide resin, or the like.

The second anode connection electrodes ANDE2 may be disposed on the first organic film 160. The second anode connection electrodes ANDE2 may be respectively connected to the first anode connection electrodes ANDE1 through second anode contact holes ANCT2 penetrating through the first organic film 160 to the first anode connection electrodes ANDE1. The second anode connection electrodes ANDE2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second organic film 180 may be disposed on the second anode connection electrodes ANDE2. The second organic film 180 may be formed as an organic film made of an acrylic resin, an epoxy resin, a phenolic resin, a polyamide resin, a polyimide resin, or the like.

FIG. 5 illustrates an example in which the first thin film transistor ST1 is a top gate type in which the first gate electrode TG1 is positioned above the first active layer ACT1, but the present disclosure is not limited thereto. The first thin film transistor ST1 may be a bottom gate type in which the first gate electrode TG1 is positioned below the first active layer ACT1 or a double gate type in which the first gate electrodes TG1 are positioned both above and below the first active layer ACT1.

The light emitting element layer EML may be disposed on the second organic film 180. The light emitting element layer EML may include light emitting elements 170 and a bank 190. Each of the light emitting elements 170 may include a first light emitting electrode 171, the light emitting layer 172, and a second light emitting electrode 173.

The first light emitting electrodes 171 may be formed on the second organic film 180. Each of the first light emitting electrode 171 may be connected to an associated one of the second anode connection electrodes ANDE2 through a third anode contact hole ANCT3 penetrating through the second organic film 180 to the associated second anode connection electrode ANDE2.

In a top emission structure which emits light from the light emitting layer 172 through the second light emitting electrode 173, the first light emitting electrode 171 may be made of a metal material having high reflectivity, such as a stacked structure (Ti/Al/Ti) of aluminum and titanium, a stacked structure (ITO/Al/ITO) of aluminum and indium tin oxide (ITO), a silver palladium coper (APC) alloy, and a stacked structure (ITO/APC/ITO) of an APC alloy and ITO. The APC alloy is an alloy of silver (Ag), palladium (Pd), and copper (Cu).

The bank 190 may partition the first light emitting electrodes 171 on the second organic film 180 to define emission areas EA. The bank 190 may include openings exposing at least portions of upper surfaces of the first light emitting electrodes 171. The bank 190 may cover edges of the first light emitting electrodes 171. The bank 190 may be an organic film made of an acrylic resin, an epoxy resin, a phenolic resin, a polyamide resin, a polyimide resin, or the like.

The emission area EA refers to an area where the first light emitting electrode 171, the light emitting layer 172, and the second light emitting electrode 173 are sequentially stacked and holes from the first light emitting electrode 171 and electrons from the second light emitting electrode 173 are combined with each other in the light emitting layer 172 to emit light. The emission area EA may be defined by the opening of the bank 190.

The light emitting layer 172 may be formed on the first light emitting electrode 171 and the bank 190. The light emitting layer 172 may be disposed in the opening of the bank 190 but is not limited thereto. The light emitting layer 172 may include an organic material selected and structured to emit light of a predetermined color. For example, the light emitting layer 172 may include a hole transporting layer, an organic material layer, and an electron transporting layer.

The second light emitting electrode 173 may be disposed on the light emitting layer 172. The second light emitting electrode 173 may be formed to cover the light emitting layer 172. The second light emitting electrode 173 may be a common layer that extends over all emission areas EA. Although not illustrated in FIG. 5, in some embodiments, a capping layer may be formed on the second light emitting electrode 173.

In the top emission structure, the second light emitting electrode 173 may be made of transparent conductive oxide (TCO) such as indium tin oxide (ITO) or indium zinc oxide (IZO) capable of transmitting light therethrough or a semi-transmissive layer of a conductive material such as magnesium (Mg), silver (Ag), or an alloy of magnesium (Mg) and silver (Ag). When the second light emitting electrode 173 is a semi-transmissive layer of conductive material, a micro cavity may increase light emission efficiency.

The thin film encapsulation layer TFEL may be disposed on the second light emitting electrode 173. The thin film encapsulation layer TFEL may include at least one inorganic film in order to prevent oxygen or moisture from permeating into the light emitting element layer 172. In addition, the thin film encapsulation layer TFEL may include at least one organic film in order to protect the light emitting element layer 172 from foreign substances such as dust. For example, the thin film encapsulation layer TFEL may include a first encapsulation film TFE1, a second encapsulation film TFE2, and a third encapsulation film TFE3.

The first encapsulation film TFE1 (e.g., a first inorganic encapsulation film) may be disposed on the second light emitting electrode 173. The first encapsulation film TFE1 may be a single-layer or multilayer inorganic film. The first encapsulation film TFE1 may include one or more inorganic films such as a silicon nitride layer, a silicon oxynitride layer, a silicon oxide layer, a titanium oxide layer, and an aluminum oxide layer, which may form a single film or may be stacked in a multi-film structure.

The second encapsulation film TFE2 (e.g., a first organic encapsulation film) may be disposed on the first encapsulation film TFE1. The second encapsulation film TFE2 may be a single-layer or multilayer organic film. The second encapsulation film TFE2 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, and an acrylic resin (e.g., polymethyl methacrylate, polyacrylic acid, etc.), or any combinations thereof.

The third encapsulation film TFE3 (e.g., a second inorganic encapsulation film) may be disposed on the second encapsulation film TFE2. The third encapsulation film TFE3 may be a single-layer or multilayer inorganic film. The third encapsulation film TFE3 may include the same material as the first encapsulation film TFE1. For example, the third encapsulation film TFE3 may include a single film or multiple films including one or more inorganic films such as a silicon nitride layer, a silicon oxynitride layer, a silicon oxide layer, a titanium oxide layer, and an aluminum oxide layer.

The touch sensor layer TSU may be disposed on the thin film encapsulation layer TFEL. The touch sensor layer TSU may include a plurality of touch electrodes for sensing a user's touch in a capacitance manner and touch lines connecting the plurality of touch electrodes to a touch driver. For example, the touch sensor layer TSU may sense the user's touch in a mutual capacitance manner or a self-capacitance manner.

In another embodiment, the touch sensor layer TSU may be disposed on a separate substrate disposed on the display layer DU. In this case, the substrate supporting the touch sensor layer TSU may be an encapsulation member encapsulating the display layer DU.

The plurality of touch electrodes of the touch sensor layer TSU may be disposed in a touch sensor area overlapping the display area. The touch lines of the touch sensor layer TSU may extend into a touch peripheral area overlapping the non-display area.

The touch sensor layer TSU may include a first touch insulating film SIL1, first touch electrodes REL, a second touch insulating film SIL2, second touch electrodes TEL, and a third touch insulating film SIL3.

The first touch insulating film SIL1 may be disposed on the thin film encapsulation layer TFEL. The first touch insulating film SIL1 may have insulating and optical functions. The first touch insulating film SIL1 may include at least one inorganic film. For example, the first touch insulating film SIL1 may be an inorganic film including at least one of a silicon nitride layer, a silicon oxynitride layer, a silicon oxide layer, a titanium oxide layer, and an aluminum oxide layer. Optionally, the first touch insulating film SIL1 may be omitted.

The first touch electrodes REL may be disposed on the first touch insulating film SIL1. The first touch electrodes REL may not overlap the light emitting elements 170. The first touch electrodes REL may be formed as a single layer made of molybdenum (Mo), titanium (Ti), copper (Cu), aluminum (Al), or ITO or be formed as a stacked structure (Ti/Al/Ti) of aluminum and titanium, a stacked structure (ITO/Al/ITO) of aluminum and ITO, an APC alloy, or a stacked structure (ITO/APC/ITO) of an APC alloy and ITO.

The second touch insulating film SIL2 may cover the first touch electrodes REL and the first touch insulating film SIL1. The second touch insulating film SIL2 may have insulating and optical functions. For example, the second touch insulating film SIL2 may be made of the material used in the first touch insulating film SIL1.

The second touch electrodes TEL may be disposed on the second touch insulating film SIL2. The second touch electrodes TEL may not overlap the light emitting elements 170. The second touch electrodes TEL may be formed as a single layer made of molybdenum (Mo), titanium (Ti), copper (Cu), aluminum (Al), or ITO or be formed as a stacked structure (Ti/Al/Ti) of aluminum and titanium, a stacked structure (ITO/Al/ITO) of aluminum and ITO, an APC alloy, or a stacked structure (ITO/APC/ITO) of an APC alloy and ITO.

The third touch insulating film SIL3 may cover the second touch electrodes TEL and the second touch insulating film SIL2. The third touch insulating film SIL3 may have insulating and optical functions. The third touch insulating film SIL3 may be made of the material used in the second touch insulating film SIL2.

In some embodiments, the first touch insulating film SIL1, the second touch insulating film SIL2, and the third touch insulating film SIL3 may be organic films. For example, the first touch insulating film SIL1, the second touch insulating film SIL2, and the third touch insulating film SIL3 may be organic films made of an acrylic resin, an epoxy resin, a phenolic resin, a polyamide resin, a polyimide resin, or the like.

The touch sensor layer TSU may further include a planarization film PAS for planarization. The planarization film PAS may be formed as an organic film made of an acrylic resin, an epoxy resin, a phenolic resin, a polyamide resin, a polyimide resin, or the like.

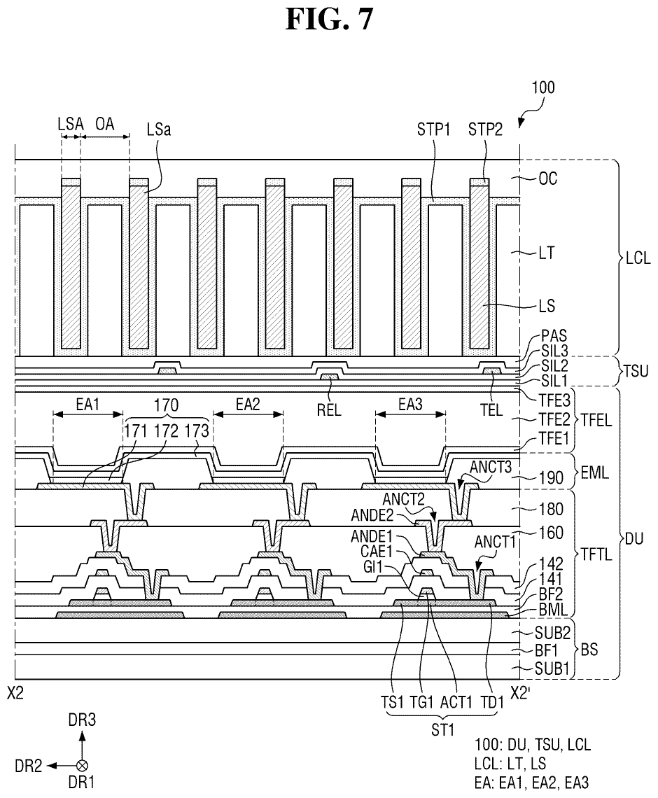

FIG. 6 is a plan view illustrating a portion of a display area according to an embodiment. FIG. 7 is a cross-sectional view taken along line X2-X2′ of FIG. 6.

Referring to FIGS. 6 and 7 in addition to FIGS. 1 and 2, the display area DA of the display device 10 may include a plurality of emission areas EA. Each emission area EA may be an area where light from one or more underlying light emitting elements 170 is emitted. The bank 190 may define the emission areas EA. For example, the plurality of emission areas EA may be areas overlapping the light emitting layers 172 disposed in the openings of the bank 190. Each emission area EA may be an area where the first light emitting electrode 171, the light emitting layer 172, and the second light emitting electrode 173 are sequentially stacked while overlapping each other.

In some embodiments, the plurality of emission areas EA may include a first emission area EA1, a second emission area EA2, and a third emission area EA3. FIGS. 6 and 7 illustrates an example in which three types of emission areas EA are included in the display area DA, but the present disclosure is not limited thereto, and the display area DA may include more or fewer than the three types of emission areas EA.

The first emission area EA1 may emit light of a first color, the second emission area EA2 may emit light of a second color, and the third emission area EA3 may emit light of a third color. The light of the first color may be light in a red wavelength band, the light of the second color may be light in a green wavelength band, and the light of the third color may be light in a blue wavelength band. The red wavelength band may be a wavelength band from about 600 nm to about 750 nm, the green wavelength band may be a wavelength band from about 480 nm to about 560 nm, and the blue wavelength band may be a wavelength band from about 370 nm to about 460 nm, but the present disclosure is not limited thereto.

Each of the first to third emission areas EA1, EA2, and EA3 may have a rectangular, square, or rhombic shape in plan view. For example, as illustrated in FIG. 6, each of the first to third emission areas EA1, EA2, and EA3 may have a rectangular shape with rounded corners, but the disclosure is not limited thereto.

In an embodiment, areas of the first to third emission areas EA1, EA2, and EA3 may be the same as each other. The first to third emission areas EA1, EA2, and EA3 may each have longer sides extending in the first direction DR1, have shorter sides extending in the second direction DR2, and may be arranged side by side in the second direction DR2.

In another embodiment, areas of the first to third emission areas EA1, EA2, and EA3 may be different from each other. The first to third emission areas EA1, EA2, and EA3 may have longer sides extending in the second direction DR2 and may be arranged side by side along the first direction DR1.

FIG. 6 illustrates an example where the transmissive areas OA and the non-transmissive areas LSA have longest dimensions extending in the first direction DR1 as in the display device 10 according to an embodiment of FIG. 1 by way of example.

The emission area EA of the display area DA may overlap the transmissive areas OA and the non-transmissive areas LSA in the third direction DR3. For example, the first to third emission areas EA1, EA2, and EA3 may overlap the transmissive areas OA and the non-transmissive areas LSA in the third direction DR3.

The transmissive area OA may be an area where the light blocking film LS of the light control layer LCL is not disposed. The non-transmissive area LSA may be an area where the light blocking film LS of the light control layer LCL is disposed.

The light control layer LCL may be disposed on the display layer DU or the touch sensor layer TSU. The light control layer LCL may control a viewing angle of the light emitted from the light emitting layer 172. For example, when the light emitted from the light emitting layer 172 travels at a predetermined angle or less with respect to the third direction DR3, the light may be emitted to the outside for viewing at angles up to the predetermined angle. On the other hand, when the light emitted from the light emitting layer 172 propagates at an angle greater than the predetermined angle with respect to the third direction DR3, the blocking film LS may absorb or block the light and thus, prevent the light from being emitted to the outside.

The light control layer LCL may include the light transmitting film LT, the light blocking film LS, a first stopper layer STP1, a second stopper layer STP2, and an overcoat layer OC.

The light transmitting film LT may transmit the light emitted from the light emitting layer 172. The light transmitting film LT may include a transparent organic material. For example, the light transmitting film LT may include an organic film made of an acrylic resin, an epoxy resin, a phenolic resin, a polyamide resin, a polyimide resin, or the like.

The light transmitting film LT may be disposed on the display layer DU or the touch sensor layer TSU. The light transmitting film LT may be disposed in the transmissive area OA. Separated regions of the light transmitting film LT may be interspersed with separated regions of the light blocking film LS in the first direction DR1 or the second direction DR2.

In some embodiments, the light transmitting film LT may include a plurality of openings corresponding to the non-transmissive area LSA. The light blocking film LS and at least portions of the first stopper layer STP1 may be disposed in the openings of the light transmitting film LT.

In some embodiments, the regions of the light transmitting film LT may be spaced apart from each other. For example, separated regions of the light transmitting film LT may be spaced apart from each other in the first direction DR1 or the second direction DR2.

The first stopper layer STP1 may be disposed on the light transmitting film LT. The first stopper layer STP1 may overlap the transmissive areas OA and the non-transmissive areas LSA. The first stopper layer STP1 may be conformally disposed on the light transmitting film LT. For example, the first stopper layer STP1 may cover an upper surface of the light transmitting film LT and inner surfaces of the openings of the light transmitting film LT.

In some embodiments, the first stopper layer STP1 may include a transparent inorganic material. For example, the first stopper layer STP1 may include at least one of silicon oxide (SiOx), silicon nitride (SiNx), and silicon oxynitride (SiOxNy).

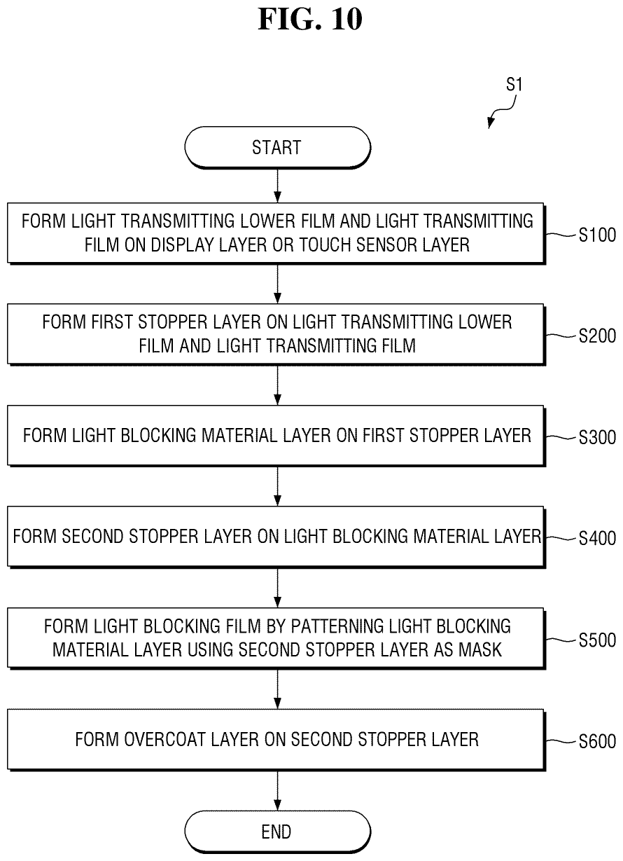

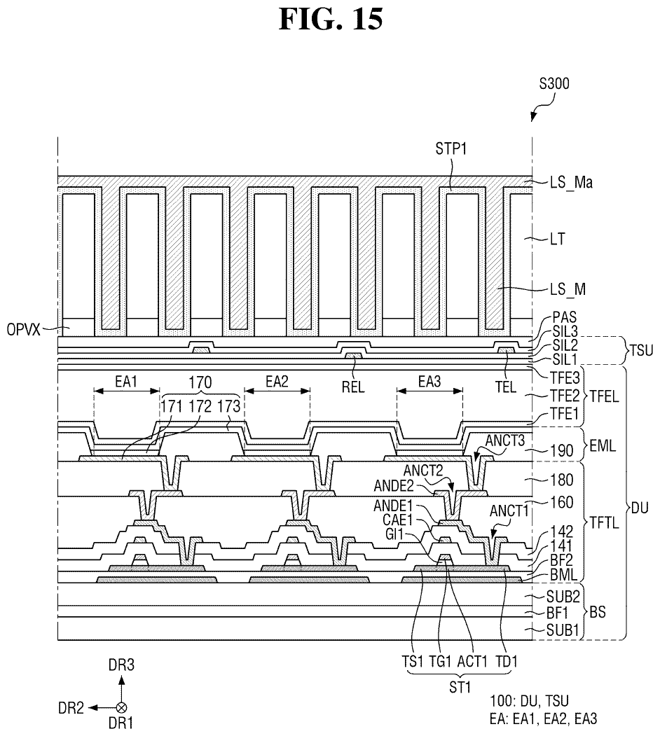

The first stopper layer STP1 may prevent the light transmitting film LT disposed in the transmissive area OA from being etched when an overflow portion LS_Ma (see FIG. 15) of a light blocking material layer LS_M (see FIG. 15) is removed in a method S1 (see FIG. 10) of manufacturing a display device described below. The first stopper layer STP1 may function as a stopper so as to prevent the light transmitting film LT from being etched beyond the overflow portion LS_Ma (see FIG. 15) of the light blocking material layer LS_M (see FIG. 15). By including inorganic material in the first stopper layer STP1, the display device 10 according to the present embodiment may prevent the light transmitting film LT, which includes an organic material, from being etched when the light blocking material layer LS_M (see FIG. 15) including an organic material is removed.

The light blocking film LS may absorb or block the light emitted from the light emitting layer 172. The light blocking film LS may include a light blocking organic material. For example, the light blocking film LS is made of a photosensitive resin capable of absorbing or blocking light and may include an organic material including an organic black pigment such as carbon black.

The light blocking film LS may be disposed on the first stopper layer STP1. The regions of the light blocking film LS and the regions of the light transmitting film LT may be disposed alternately or interwoven in the first direction DR1 or the second direction DR2. For example, the light blocking film LS may be disposed within the openings of the light transmitting film LT.

The light blocking film LS may include a protrusion portion LSa. The protrusion portion LSa may be a portion of the light blocking film LS protruding in the third direction DR3 from the upper surface of the light transmitting film LT or an upper surface of the first stopper layer STP1.

The second stopper layer STP2 may be disposed on the regions of the light blocking film LS. For example, the second stopper layer STP2 may include a plurality of separate regions, and the plurality of regions of the second stopper layer STP2 may be respectively disposed on a plurality of regions of the light blocking film LS. The regions of the second stopper layer STP2 may be respectively disposed on the regions of the light blocking film LS, so as to correspond in a one-to-one manner with the regions of the light blocking film LS. The second stopper layer STP2 may be disposed in the non-transmissive areas LSA.

In some embodiments, the second stopper layer STP2 may include a transparent inorganic material. For example, the second stopper layer STP2 may include at least one of silicon oxide (SiOx), silicon nitride (SiNx), and silicon oxynitride (SiOxNy).

The second stopper layer STP2 may prevent the light blocking material layer LS_M (see FIG. 15) disposed in the non-transmissive area LSA from being etched when the overflow portion LS_Ma (see FIG. 15) of the light blocking material layer LS_M (see FIG. 15) is removed in a method S1 (see FIG. 10) of manufacturing a display device described below. The second stopper layer STP2 may function as a stopper or a mask so as to prevent the light blocking material layer LS_M (see FIG. 15) disposed in the non-transmissive area LSA in addition to the overflow portion LS_Ma (see FIG. 15) of the light blocking material layer LS_M (see FIG. 15) disposed in the transmissive area OA from being etched.

The display device 10 according to the present embodiment may prevent a portion of the non-transmissive area LSA from being etched when the light blocking material layer LS_M (see FIG. 15) of the transmissive area OA including the organic material is removed, by including an inorganic material in the second stopper layer STP2. In addition, in the display device 10 according to the present embodiment, the second stopper layer STP2 including the inorganic material may be directly deposited on the light blocking film LS, and thus, an additional organic film does not need to be formed on the light blocking film LS in order to use a metal hard mask, such that a process may be simplified and process efficiency may be improved.

The overcoat layer OC may be disposed on the first stopper layer STP1, the light blocking film LS, and the second stopper layer STP2. The overcoat layer OC may cover the upper surface of the first stopper layer STP1, side surfaces of the protrusion portions LSa of the light blocking film LS, and an upper surface of the second stopper layer STP2.

The overcoat layer OC may include an organic film made of an acrylic resin, an epoxy resin, a phenolic resin, a polyamide resin, a polyimide resin, or the like.

The display device 10 according to the present embodiment may prevent a height of the light transmitting film LT from being lowered by including the first stopper layer STP1 and may prevent a height of the light blocking film LS from being lowered by including the second stopper layer STP2. Accordingly, control of a viewing angle of the light control layer LCL may be improved.

Hereinafter, other embodiments of the display device are described. In the following embodiments, components that are the same as those of the above-described embodiment are denoted by the same reference numerals, and an overlapping description thereof may be omitted or simplified and differences from those described above primarily described.

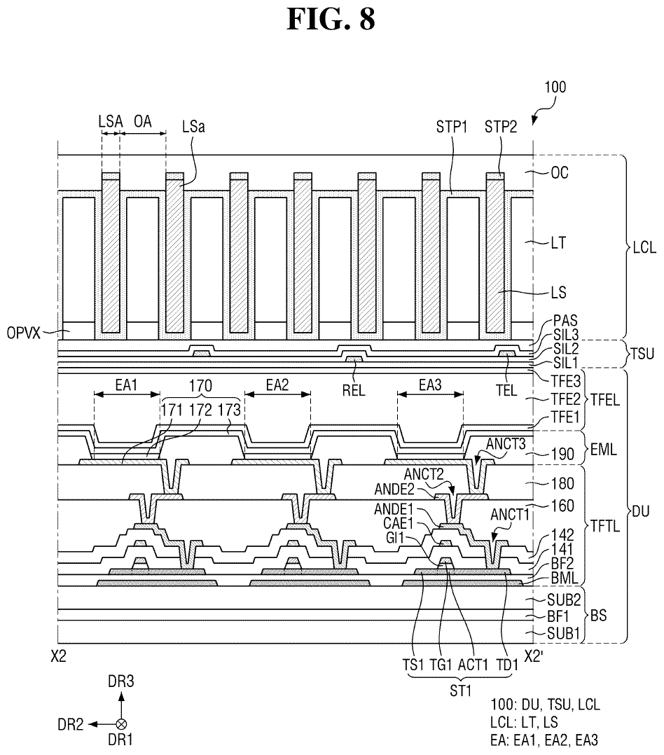

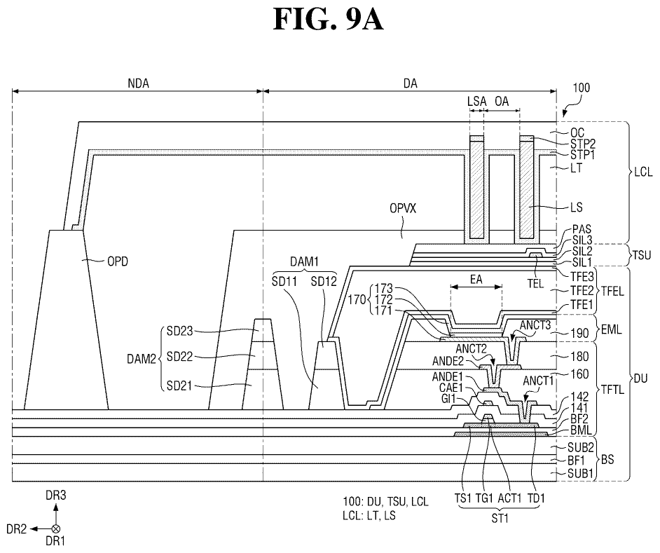

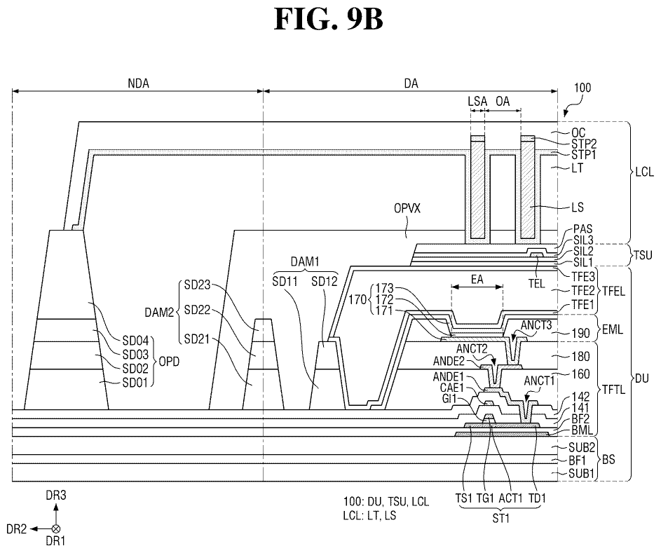

FIG. 8 is a cross-sectional view illustrating an example of a display panel according to an embodiment. FIG. 9A is a cross-sectional view illustrating portions of a display area and a non-display area of a display panel according to an embodiment. FIG. 9B is a cross-sectional view illustrating portions of a display area and a non-display area of a display panel according to an embodiment.

Display devices 10 according to the illustrated embodiments of FIGS. 8, 9A, and 9B differ from the display device 10 according to the embodiment described with reference to FIG. 7 and the like in that the embodiments of FIGS. 8, 9A, and 9B further include a light transmitting lower film OPVX and a light transmitting film dam OPD.

The light control layer LCL in these embodiments may further include the light transmitting lower film OPVX. The light transmitting lower film OPVX may transmit the light emitted from the light emitting layer 172. The light transmitting lower film OPVX may include a transparent organic material. For example, the light transmitting lower film OPVX may include an organic film made of an acrylic resin, an epoxy resin, a phenolic resin, a polyamide resin, a polyimide resin, or the like.

The light transmitting lower film OPVX may be disposed on the display layer DU or the touch sensor layer TSU. The light transmitting lower film OPVX may be disposed below the light transmitting film LT. The light transmitting lower film OPVX may be disposed in the transmissive area OA. Regions of the light transmitting lower film OPVX and regions of the light blocking film LS may be disposed alternately or interwoven in the first direction DR1 or the second direction DR2.

The light transmitting lower film OPVX may include a plurality of openings that are in the non-transmissive areas LSA. The light blocking film LS and at least portions of the first stopper layer STP1 may be disposed in the openings of the light transmitting lower film OPVX. The openings of the light transmitting lower film OPVX may be formed integrally with the openings of the light transmitting film LT.

In some embodiments, a plurality of regions of the light transmitting lower film OPVX may be respectively disposed below the plurality of regions of the light transmitting film LT. The regions of the light transmitting lower film OPVX may be respectively disposed below the regions of the light transmitting film LT, so as to correspond to the regions of light transmitting film LT in a one-to-one manner.

The display panel 100 may further include a first dam DAM1, a second dam DAM2, and the light transmitting film dam OPD.

FIGS. 9A and 9B illustrate examples in which the first dam DAM1 is disposed in the display area DA, the second dam DAM2 is disposed in the display area DA and the non-display area NDA, and the light transmitting film dam OPD is disposed in the non-display area NDA, but the present disclosure is not limited thereto. In another embodiment, the first dam DAM1, the second dam DAM2, and the light transmitting film dam OPD may all be disposed in the non-display area NDA or may all be disposed in the display area DA.

The first dam DAM1, the second dam DAM2, and the light transmitting film dam OPD may be disposed on the base member BS. As illustrated in FIGS. 9A and 9B, when the second buffer film BF2, the first interlayer insulating film 141, and the second interlayer insulating film 142 extend to lower portions of the first dam DAM1, the second dam DAM2, and the light transmitting film dam OPD, the first dam DAM1, the second dam DAM2, and the light transmitting film dam OPD may be disposed on the second buffer film BF2, the first interlayer insulating film 141, and the second interlayer insulating film 142. In an embodiment, when the second buffer film BF2, the first interlayer insulating film 141, and the second interlayer insulating film 142 do not extend to lower portions of the first dam DAM1, the second dam DAM2, and the light transmitting film dam OPD, the first dam DAM1, the second dam DAM2, and the light transmitting film dam OPD may be directly on the base member BS.

The first dam DAM1 and the second dam DAM2 may prevent the second encapsulation film TFE2 of the thin film encapsulation layer TFEL from overflowing into the non-display area NDA or outside of the display panel 100. FIGS. 9A and 9B illustrate examples in which the display panel 100 includes two dams in addition to the light transmitting film dam OPD, but the present disclosure is not limited thereto. The display panel 100 may also include one dam or three or more dams in addition to the light transmitting film dam OPD.

The first dam DAM1 may include a first sub-dam SD11 and a second sub-dam SD12, and the second dam DAM2 includes a first sub-dam SD21, a second sub-dam SD22, and a third sub-dam SD23. The first sub-dams SD11 and SD21 may include the same material as the first organic film 160 and may be formed from the same layer as the first organic film 160. The second sub-dams SD12 and SD22 may include the same material as the second organic film 180 and may be formed from the same layer as the second organic film 180. The third sub-dam SDA23 may be on the second sub-dam SD22 and may include the same material as the second sub-dam SD22. In another embodiment, the third sub-dam SD23 may include the same material as the bank 190 and may be formed from the same layer as the bank 190.

A height of the first dam DAM1 may be lower than a height of the second dam DAM2. However, the present disclosure is not limited thereto, and the height of the first dam DAM1 may be substantially the same as the height of the second dam DAM2 or may be higher than the height of the second dam DAM2.

In some embodiments, the light transmitting lower film OPVX may extend from the display area DA toward the non-display area NDA. The light transmitting lower film OPVX may completely cover an upper surface and side surfaces of the first dam DAM1 and an upper surface and side surfaces of the second dam DAM2.

The light transmitting film dam OPD may prevent the light transmitting film LT from overflowing into the non-display area NDA or the outside of the display panel 100. FIGS. 9A and 9B illustrate examples in which the display panel 100 includes one light transmitting film dam OPD, but the present disclosure is not limited thereto. The display panel 100 may include two or more light transmitting film dams OPD.

The light transmitting film LT may be disposed inside the light transmitting film dam OPD. For example, the light transmitting film LT may be disposed closer to the light emitting elements 170 than the light transmitting film dam OPD is. The light transmitting film dam OPD may define a boundary and may keep the light transmitting film LT inside the boundary, so that the light transmitting film LT does not extend beyond the light transmitting film dam OPD.

In some embodiments, as illustrated in FIG. 9A, the light transmitting film dam OPD may include a single layer. For example, the light transmitting film dam OPD may include the same material as the light transmitting lower film OPVX and may be formed from the same layer from which the light transmitting lower film OPVX is formed.

In another embodiment, as illustrated in FIG. 9B, the light transmitting film dam OPD may include a plurality of layers. For example, the light transmitting film dam OPD may include a first sub-dam SD01, a second sub-dam SD02, a third sub-dam SD03, and a fourth sub-dam SD04. The fourth sub-dam SDAM4 may include the same material as the light transmitting lower film OPVX, and the first, second, and third sub-dams SD01, SD02, and SD03 may respectively be formed from the same materials as the first organic film 160, the second organic film 180, and the bank 190.

In some embodiments, the light transmitting film LT may be formed by an inkjet printing process. The light transmitting lower film OPVX may be formed by a deposition process. The light transmitting film LT may include a different material from the light transmitting lower film OPVX. For example, the light transmitting film LT may include an ester-based compound and a phosphine oxide compound. Specifically, the ester-based compound may contain carbon atoms of 30 or less. The light transmitting lower film OPVX may include propylene glycol methyl ether acetate, ethacrylic acid-benzylmethacrylic acid copolymer, and multi-functional acrylate, and a photo initiator.

In some embodiments, the overcoat layer OC may be formed by a deposition process like the light transmitting lower film OPVX. The overcoat layer OC may include propylene glycol methyl ether acetate, ethacrylic acid-benzylmethacrylic acid copolymer, and multi-functional acrylate, and a photo initiator, like the light transmitting lower film OPVX.

Hereinafter, a method of manufacturing a display device according to an embodiment is described.

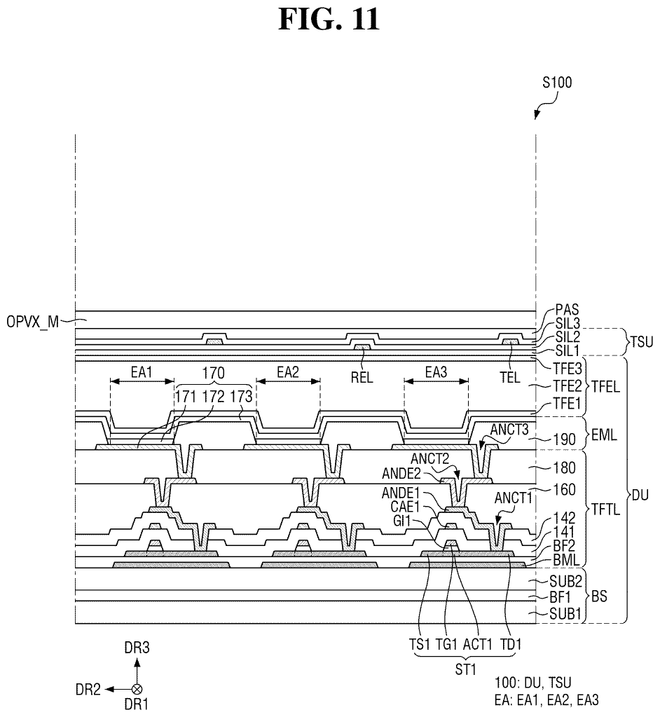

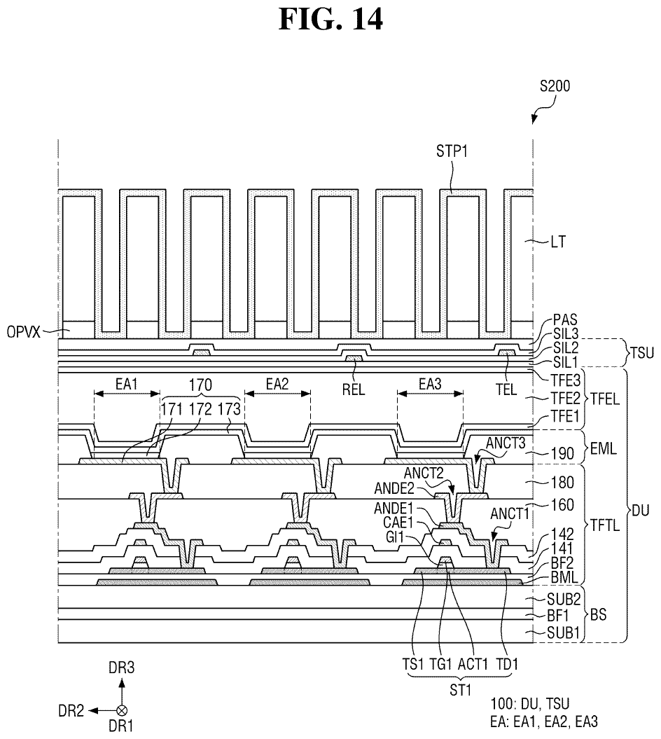

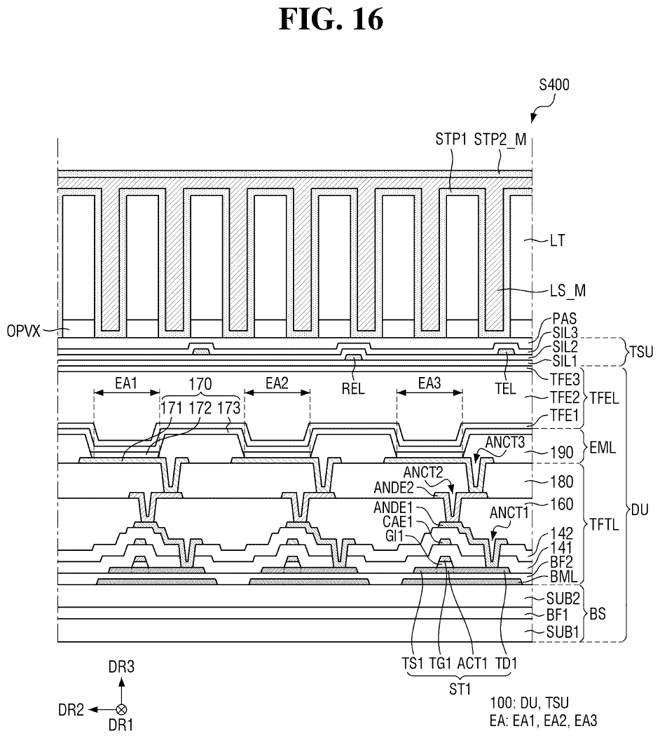

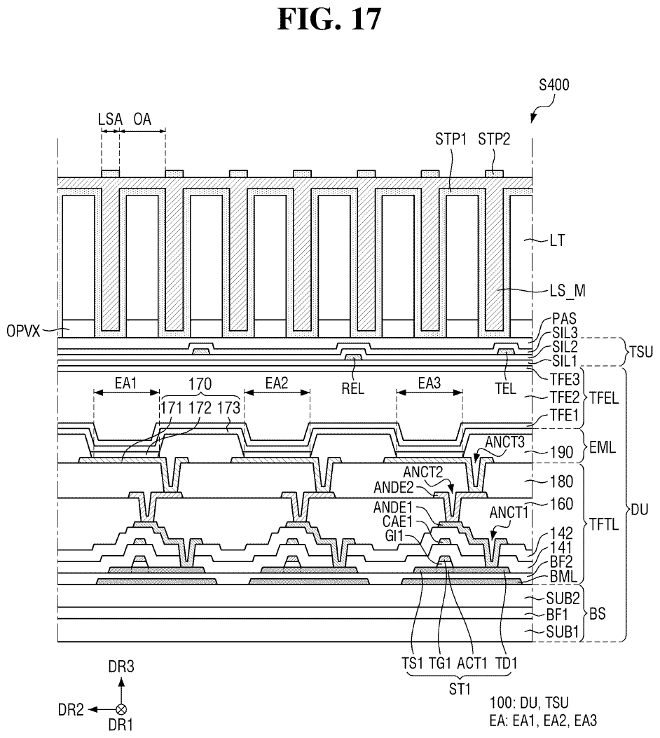

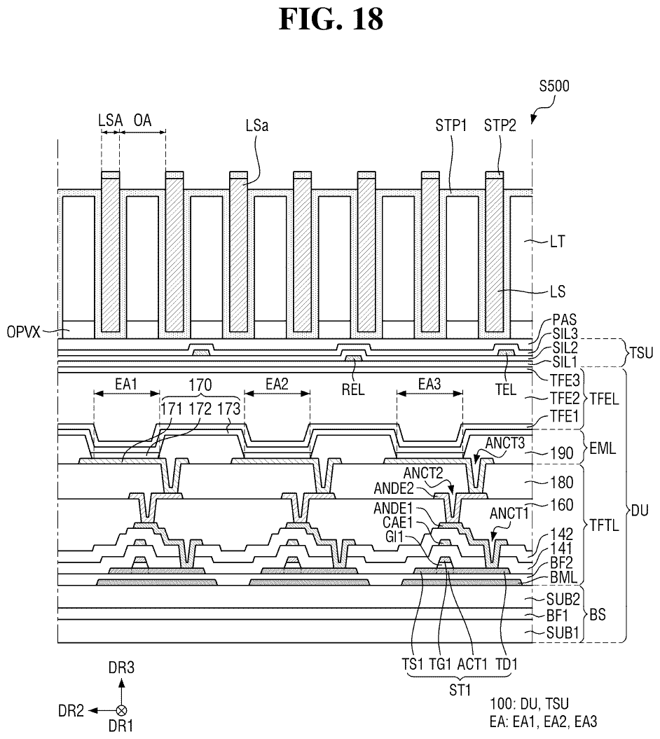

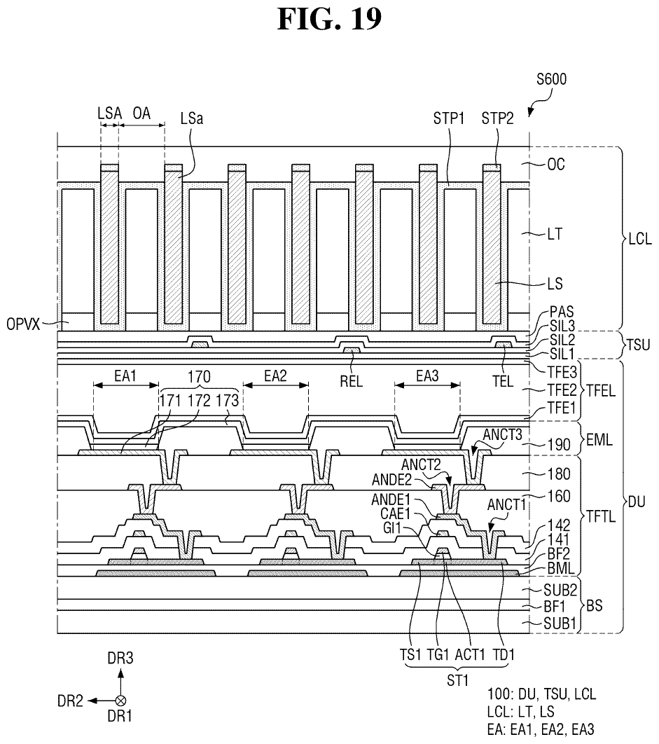

FIG. 10 is a flowchart illustrating a method of manufacturing a display device according to an embodiment. FIGS. 11 to 13 are cross-sectional views illustrating structures formed during an embodiment of a process S100 of FIG. 10. FIG. 14 is a cross-sectional view illustrating structures formed during an embodiment of a process S200 of FIG. 10. FIG. is a cross-sectional view illustrating structures formed during an embodiment of a process S300 of FIG. 10. FIGS. 16 and 17 are cross-sectional views illustrating structures formed during an embodiment of a process S400 of FIG. 10. FIG. 18 is a cross-sectional view illustrating structures formed during an embodiment of a process S500 of FIG. 10. FIG. 19 is a cross-sectional view illustrating structures formed during an embodiment of a process S600 of FIG. 10.

Referring to FIGS. 10 to 19, a method S1 of manufacturing a display device according to an embodiment may include a process S100 forming a light transmitting lower film and a light transmitting film, a process S200 forming a first stopper layer, a process S300 forming a light blocking material layer, a process S400 forming a second stopper layer, a process S500 forming a light blocking film, and a process S600 forming an overcoat layer.

As illustrated in FIGS. 11 to 13, in the process S100 forming the light transmitting lower film and the light transmitting film, the light transmitting lower film OPVX and the light transmitting film LT may be formed on the display layer DU or the touch sensor layer TSU. The light transmitting lower film OPVX and the light transmitting film LT may be formed by a photolithography process and an inkjet printing process. For example, a light transmitting lower material layer OPVX_M as shown in FIG. 11 may be formed on the display layer DU or the touch sensor layer TSU by a deposition process.

Although not illustrated in FIGS. 11 to 13, the light transmitting film dam OPD described above with reference to FIGS. 9A and 9B may be formed in a process of forming the light transmitting lower material layer OPVX_M.

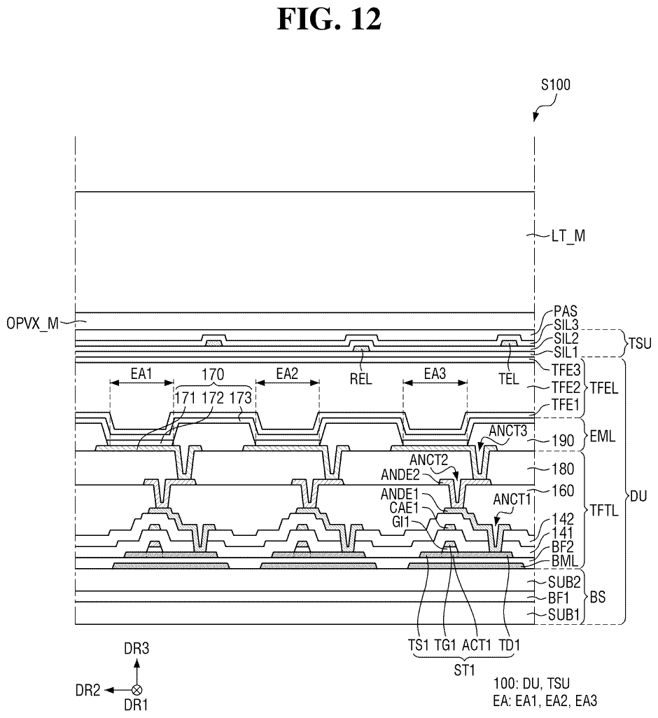

Next, a light transmitting material layer LT_M may be formed on the light transmitting lower material layer OPVX_M as shown in FIG. 12. The light transmitting material layer LT_M may be formed by an inkjet printing process. When the light transmitting material layer LT_M is formed by the inkjet printing process, the overflow of the light transmitting material layer LT_M may be prevented by the light transmitting film dam OPD (see FIGS. 9A and 9B).

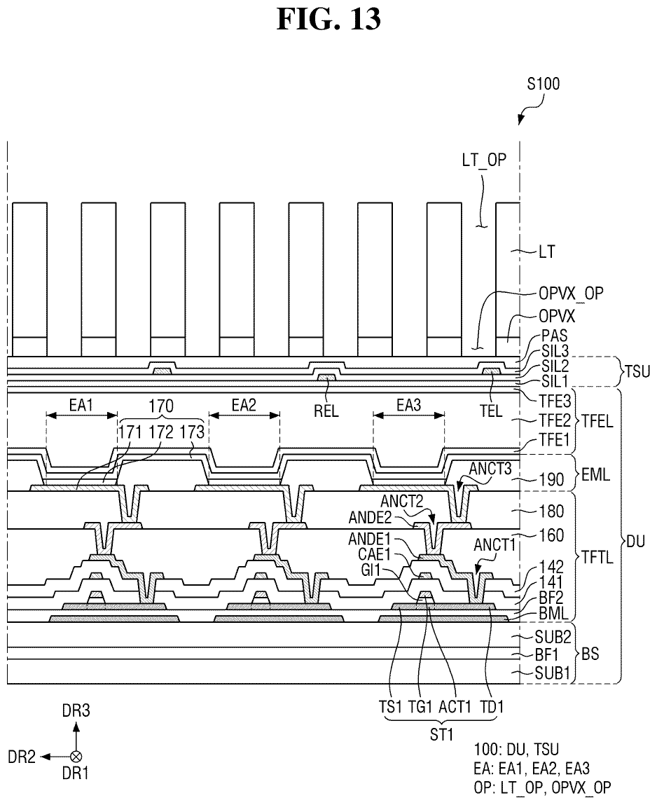

Next, the light transmitting film LT and the light transmitting lower film OPVX may be formed as shown in FIG. 13 by patterning the light transmitting material layer LT_M and the light transmitting lower material layer OPVX_M. The patterning of the light transmitting material layer LT_M and the light transmitting lower material layer OPVX_M may be performed by a photolithography process. Accordingly, openings LT_OP in the light transmitting film LT and openings OPVX_OP in the light transmitting lower film OPVX may be formed. The openings LT_OP in the light transmitting film LT and the openings OPVX_OP in the light transmitting lower film OPVX together form integrated openings OP.

As illustrated in FIG. 14, in the process S200 forming the first stopper layer, the first stopper layer STP1 may be disposed on the display layer DU or the touch sensor layer TSU, the light transmitting lower film OPVX, and the light transmitting film LT. For example, the first stopper layer STP1 may be formed on inner surfaces of the openings OP and an upper surface of the light transmitting film LT. The first stopper layer STP1 may be formed by a deposition process.

As illustrated in FIG. 15, in the process S300 forming the light blocking material layer, the light blocking material layer LS_M may be formed on the first stopper layer STP1. For example, the light blocking material layer LS_M may fill inner portions of the openings OP. The light blocking material layer LS_M may also be formed on the light transmitting film LT and the openings OP by overflowing from the openings OP. The light blocking material layer LS_M may include an overflow portion LS_Ma positioned higher than the upper surface of the light transmitting film LT or an upper surface of the first stopper layer STP1.

As illustrated in FIGS. 16 and 17, in the process S400 forming the second stopper layer, the second stopper layer STP2 may be formed on the light blocking material layer LS_M. The second stopper layer STP2 may be formed or patterned by a photolithography process.

For example, a stopper material layer STP2_M as shown in FIG. 16 may be formed on the light blocking material layer LS_M by a deposition process. Next, the second stopper layer STP2 as shown in FIG. 17 may be formed by patterning the stopper material layer STP2_M. The patterning of the stopper material layer STP2_M may be performed by a photolithography process.

As illustrated in FIG. 18, in the process S500 forming the light blocking film, the light blocking material layer LS_M may be patterned using the second stopper layer STP2 as a mask. The light blocking film LS may thus be formed by patterning the light blocking material layer LS_M.

Although not illustrated in the drawings, a patterning process of the stopper material layer STP2_M and a patterning process of the light blocking material layer LS_M may be continuously performed but may be proceed at different etch rates. For example, the stopper material layer STP2_M includes an inorganic material and the light blocking material layer LS_M includes an organic material, and thus, the patterning process of the stopper material layer STP2_M and the patterning process of the light blocking material layer LS_M may be performed as a continuous process by adjusting an etch rate of an etchant. Accordingly, process efficiency may be improved.

According to the method S1 of manufacturing a display device 10 according to the present embodiment, the second stopper layer STP2 including the inorganic material is included, and it is thus possible to prevent a non-transmissive area LSA portion from being etched when the light blocking material layer LS_M (see FIG. 15) of the transmissive area OA including the organic material is removed. In addition, in the display device 10 according to the present embodiment, the second stopper layer STP2 including the inorganic material may be directly deposited on the light blocking film LS, and thus, an additional organic film does not need to be formed on the light blocking film LS in order to use a metal hard mask, such that a process may be simplified and process efficiency may be improved.

By patterning the light blocking material layer LS_M, the light blocking material layer LS_M disposed in the transmissive area OA may be removed, and only the light blocking material layer LS_M disposed in the non-transmissive area LSA may remain. The light blocking film LS may include a protrusion portion LSa protruding from the upper surface of the light transmitting film LT or the upper surface of the first stopper layer STP1 in the third direction DR3.

According to the method S1 of manufacturing a display device according to the present embodiment, the first stopper layer STP1 including the inorganic material is included, and it is thus possible to prevent the light transmitting film LT including an organic material from being etched when the light blocking material layer LS_M (see FIG. 15) including organic material is removed. For example, since the first stopper layer STP1 including the inorganic material is disposed on the light transmitting film LT, a difference in the etch rates of the light blocking material layer LS_M and the first stopper layer STP1 may prevent the light transmitting film LT from being etched after the light blocking material layer LS_M disposed in the transmissive area OA is all removed.

As illustrated in FIG. 19, in the process S600 forming the overcoat layer, the overcoat layer OC may be formed on the first stopper layer STP1, the light blocking film LS, and the second stopper layer STP2. The overcoat layer OC may be formed by a photolithography process.

According to the method S1 of manufacturing a display device according to the present embodiment, the first stopper layer STP1 is included making it possible to prevent a height of the light transmitting film LT from being lowered, and the second stopper layer STP2 is included making it possible to prevent a height of the light blocking film LS from being lowered. Accordingly, a viewing angle control effect of the light control layer LCL may be improved.

According to the method S1 of manufacturing a display device according to the present embodiment, process efficiency may be improved by performing an etching process instead of a chemical mechanical polishing (CMP) process when removing the overflow portion LS_Ma. In addition, reliability of the light control layer LCL may be improved by performing the etching process instead of the CMP process requiring physical contact.

In concluding the detailed description, those skilled in the art will appreciate that many variations and modifications can be made to the example embodiments without substantially departing from the principles of the present disclosure. Therefore, the disclosed embodiments are used in a generic and descriptive sense only and not for purposes of limitation.

What is claimed is:

1. A display device comprising:
a substrate;
a light emitting element layer disposed on the substrate and including a plurality of light emitting elements; and
a light control layer disposed on the light emitting element layer,
wherein the light control layer includes:
a light transmitting film including a plurality of regions spaced apart from each other;
a first stopper layer disposed on the light transmitting film; and
a light blocking film including a plurality of regions on the first stopper layer and disposed between the regions of the light transmitting film, respectively, wherein
the first stopper layer covers upper surfaces and side surfaces of the regions of the light transmitting film.

2. The display device of claim 1, wherein the first stopper layer is conformally disposed on the regions of the light transmitting film.

3. The display device of claim 1, wherein each of the regions of the light blocking film includes a protrusion portion protruding from an upper surface of the first stopper layer or the upper surfaces of the regions of the light transmitting film.

4. The display device of claim 3, further comprising an overcoat layer disposed on the first stopper layer and the light blocking film and covering an upper surface and side surfaces of the protrusion portion.

5. The display device of claim 1, further comprising a second stopper layer disposed on the regions of the light blocking film,
wherein the second stopper layer includes a plurality of patterns respectively disposed on the regions of the light blocking film.

6. The display device of claim 5, wherein the second stopper layer includes an inorganic material, and the light transmitting film includes an organic material.

7. The display device of claim 1, wherein the light control layer further includes a light transmitting lower film including a plurality of regions respectively disposed below the regions of the light transmitting film.

8. The display device of claim 7, wherein the light transmitting lower film includes an inorganic material, and the light transmitting film includes an organic material.

9. The display device of claim 7, further comprising a dam disposed on one side of the plurality of light emitting elements on the substrate and including the same material as the light transmitting lower film.

10. The display device of claim 9, wherein the regions of the light transmitting film are disposed closer to the plurality of light emitting elements than is the dam.

11. A display device comprising:
a substrate;
a light emitting element layer disposed on the substrate and including a plurality of light emitting elements; and
a light control layer disposed on the light emitting element layer,
wherein the light control layer includes:
a light transmitting film including a plurality of first openings;
a first stopper layer disposed on the light transmitting film; and
a light blocking film including a plurality of regions disposed on the first stopper layer respectively in the plurality of first openings, wherein
the first stopper layer covers an upper surface of the light transmitting film and inner surfaces of the plurality of first openings.

12. The display device of claim 11, wherein the first stopper layer is conformally disposed on the light transmitting film.

13. The display device of claim 11, wherein each of the regions of the light blocking film includes a protrusion portion protruding from an upper surface of the first stopper layer or the upper surface of the light transmitting film.

14. The display device of claim 13, further comprising an overcoat layer disposed on the first stopper layer and the regions of the light blocking film and covering an upper surface and side surfaces of the protrusion portion.

15. The display device of claim 11, further comprising a second stopper layer disposed on the regions of the light blocking film,
wherein the second stopper layer includes a plurality of regions respectively disposed on the regions of the light blocking film.

16. The display device of claim 15, wherein the second stopper layer includes an inorganic material, and the light transmitting film includes an organic material.

17. The display device of claim 11, wherein the light control layer further includes a light transmitting lower film disposed below the light transmitting film and including a plurality of second openings, and
the plurality of second openings are formed integrally with the plurality of first openings, respectively.

18. The display device of claim 17, wherein the light transmitting lower film includes an inorganic material, and the light transmitting film includes an organic material.

19. The display device of claim 17, further comprising a dam disposed on one side of the plurality of light emitting elements on the substrate and including the same material as the light transmitting lower film.

20. The display device of claim 19, wherein the light transmitting film is disposed closer to the plurality of light emitting elements than is the dam.
